(19) United States
(12) Patent Application Publication
(10) Pub. No.: US 2008/0179728 A1
(43) Pub. Date: Jul. 31, 2008

(54) Laminated memory

(75) Inventor: Hiroaki Ikeda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/010,839

(22) Filed: Jan. 30, 2008

(30) Foreign Application Priority Data
Jan. 31, 2007 (JP) 2007-020240

(51) Int. Cl. G11C 8/00; H01L 23/02

(52) U.S. Cl. 257/686; 365/230.06; 257/E23.002

(57) ABSTRACT

A laminated memory is formed of first and second memory chips having different positions to dispose ID through electrodes for setting layer identification information of each layer. The memory chips are alternately stacked. By alternately stacking the layers, internal circuits for the layer identification information of each layer are connected in cascade. The cascade-connected internal circuits serve to identify respective layers of the first and the second memory chips. Identification of the respective layers makes it possible to selectively operate each memory chip.

This application is based upon and claims the benefit of priority from Japanese patent application No. 2007-020240, filed on Jan. 31, 2007, the disclosure of which is incorporated herein in its entirety by reference.

### BACKGROUND OF THE INVENTION

1. Field of the Invention

The present invention relates to a laminated memory or a stacked memory formed by stacking semiconductor chips using a through electrode, and more particularly, to a laminated memory and a method which can identify each layer of the stacked semiconductor chips.

2. Description of the Related Art

In recent years, semiconductor devices have been miniaturized and semiconductor memories, such as a dynamic random access memory (DRAM) and a static random access memory (SRAM), have been largely increased in capacity. However, electronic devices that mount the semiconductor memories are also downsized. Under the circumstances, in order to increase the capacities of the semiconductor memories, recent attention has been directed to three-dimensional laminated memories formed of stacked memory chips. In this event, such three-dimensional laminated memories formed of stacked memory chips are accommodated in a single package with the memory chips wire-bonded with each other. Thus, large-capacity semiconductor devices are downsized by stacking the memory chips according to the above-described manner to form the three-dimensional laminated memories.

Moreover, recently, in order to further downsize and increase operation speeds of the semiconductor devices, instead of the wire bonding, laminated memories using through electrodes have been developed. In the laminated memories, stacked memory chips are interconnected using the through electrodes that pass through the inside of the chips. The use of the through electrodes is expected to reduce spaces and inductance due to the wire bonding, further downsize the semiconductor devices, and achieve high-speed operation. Especially, in the case where the memory chips are stacked, it is possible to form ultrahigh-density and ultrahigh-capacity memory modules and memory systems. Although fine devices have been thus far employed as a major method in order to largely increase the memory capacity, using the three-dimensional laminated memories would make it possible to realize extremely large capacity over several future generations. Accordingly, recent attention and development have been focused on the three-dimensional laminated memories.

As methods for forming the through electrodes in the laminated memories, various process technologies have been proposed. The through electrodes are required to be further miniaturized in pad diameters and pitches of arrangement spaces than those in the current memory chips. To satisfy the miniaturization of the diameters and the pitches of the arrangement spaces of the through electrodes, it is difficult to apply chip to chip technologies and chip to wafer technologies that process chips after dicing process have performed. Accordingly, it is necessary to employ a wafer to wafer technology that stacks a wafer on a wafer.

There are several options about forming the through electrode in dependency upon steps of forming the through electrode that are performed within a wafer process. One of the methods is a method of forming the through electrode with respect to a wafer subjected to a diffusion process. The method is called a via-last process because the through electrode formation is performed at the end of the process. The via-last process is advantageous in that the through electrode formation and the laminate structure formation can be performed irrespective of the fabrication process of target wafers to be laminated. Accordingly, the via-last process is an appropriate selection as an advanced laminated memory fabrication technique.

Now, the via-last process is described with reference to FIGS. 1 to 5. FIG. 1 illustrates a through electrode formation and a lamination process described in non-patent document, Naotaka Tanaka et al. “Mechanical Effects of Copper Through-Vias in a 3D Die-Stacked Module”, 2002 Electronic Components and Technology Conference Proceedings, s11p 6. FIG. 1A is a cross sectional view illustrating a state where a diffusion process is finished. In FIG. 1A, a transistor (not shown) or the like is formed on a silicon substrate 1, and a pad 3 is formed in an interlayer insulation film 2. Then, a through hole 4 of 70 μm depth is formed (FIG. 1B). The internal part of the through hole 4 is considered as an electrode insulation film 5, and the electrode insulation film 5 is insulated by a oxide film (SiO₂) or the like (FIG. 1C). Further, for example, a barrier layer of titanium nitride (TiN) is formed, copper is plated by a plating method, and the through hole is filled with the through hole electrode material 5 (FIG. 1D). Then, the front surface is polished by chemical mechanical polishing to be flat, and front surface side upper bumps 7 are formed (FIG. 1E). The above steps are the fabrication process of the front surface side of the wafer.

On the front surface of the wafer, an adhesive film 8 and a protection sheet 9 are attached to each other (FIG. 1F). Then, the silicon substrate 1 is thinned to 50 μm by grinding from the rear surface of the silicon substrate 1 (FIG. 1G). On the rear surface of the silicon substrate, a nitride film (Si₃N₄) is formed as a rear surface insulation film 11, and lower bumps 12 are formed on the rear surface side of a through electrode 10 (FIG. 1H). Then, the adhesive film 8 and the protection sheet 9 on the silicon substrate front surface are removed (FIG. 1I). The semiconductor chip is stacked on an interposer 13, and the front surface of the through electrode 10 and the upper bumps 7 of the front surface side and the lower bumps 12 of the rear surface side are joined (FIG. 1J). According to the above-described process, the laminated memory that has the substantially same size as the chip size can be formed.

Further, other via-last processes are described with reference to FIGS. 2 and 3. It is assumed that the thickness of the silicon substrate is thinner than the above case, and the thickness is 30 μm or less. If the silicon substrate is thinned to have such small thickness, it is not possible to process the wafer itself. Accordingly, the silicon substrate is attached on a temporary supporting film and the silicon substrate is processed. FIG. 2A is a cross sectional view illustrating a state that a diffusion process is finished. In FIG. 2A, a transistor (not shown) or the like is formed on the silicon substrate 1, and wirings and the pad 3 are formed in an interlayer insulation film. On the wafer front surface, a temporary supporting film 15 is attached.

The silicon substrate 1 is ground from the rear surface to be a thickness of 10 μm, and a nitride film (Si₃N₄) is formed as the rear surface insulation film 11 (FIG. 2B). The ground wafer is attached on a wafer that is not grinding-processed to stack (FIG. 2C). Then, the temporary supporting film is removed (FIG. 2D). In the ground wafer, a through hole is formed so that the through hole reaches the lower layer wafer (FIG. 2E). The inside of the through hole is considered as the electrode insulation film 5, and filled with an oxide film (SiO₂) or the like (FIG. 2F). In this case, since the thickness of the silicon substrate is small, an aspect ratio becomes small, and the diameter of the through hole 4 can be reduced. Accordingly, it is possible to form the through electrode having the small diameter, and many miniaturized through electrodes can be disposed.

Then, the through hole is filled with a conductive material and the through electrode 10 connected to pads on upper and lower layers is formed. At the same time, connection wirings that are connected with the pad 3 are formed (FIG. 3A). Further, in the same manner as FIG. 2C, the thin ground wafer is attached on the wafer to stack. Then, the process steps to FIG. 3A are performed. By repeating the lamination and through electrode formation (including the formation of the internal pads and connection wirings) processes of FIG. 2C to FIG. 3A, a laminated memory of FIG. 3B is formed. In this method, to form the through electrode having the miniaturized diameter, the process of grinding the wafer to be very thin, and the process of stacking and the process of forming the through electrode are repeatedly performed.

FIGS. 4A, 4B, and 4C illustrate a structure of the laminated memory shown in FIG. 3B. FIG. 4A is a schematic view of the laminated memory, and FIG. 4B is a cross sectional view of the laminated memory. FIG. 4C is a view illustrating a chip connection of the laminated memory. The laminated memory includes six layers of memory chips 20-1 to 20-6 that have the same structure. Each memory chip has through electrodes that are formed of, for example, a command/address signal line Com/Add and a data line Data (FIGS. 4A and 4B). As shown in FIG. 4C, with the command/address signal line Com/Add and the data line Data, the memory chips of each layer are connected in parallel. Accordingly, the stacked each layer is simultaneously operated, which makes it difficult to individually and selectively operate each layer in the laminated memory.

In the above-described case of stacking the chips having the same structure, in order to individually access to each stacked layer, it is required to embed layer identification means. FIGS. 5A, 5B, and 5C illustrate a structure of the layer identification means. FIG. 5A illustrates a memory chip having a normal through electrode. The through electrode 10 is connected to the upper and lower metallic bumps 7 and 11. On the other hand, a memory chip 20 shown in FIG. 5B includes an internal circuit 30 as layer identification means between the upper and lower metallic bumps 7 and 11. A through electrode that sets layer identification information can also be used as the through electrode formed of the command/address signal line Com/Add and the data line Data. However, in the following description, to facilitate understanding, the through electrode that sets layer identification information is called an ID through electrode.

The memory chips 20 shown in FIG. 5B are stacked in a manner illustrated in FIG. 5C. The memory chips 20-1 to 20-n that form the respective layers have the internal circuits 30 operable as the layer identification means respectively. Because the internal circuits 30 in the respective layers are connected in parallel to one another, the circuits simultaneously operates in parallel. Accordingly, it is difficult to individually set each layer, and it is required to provide dedicated individual through electrodes for each layer to operate each layer individually. Alternatively, first, identification (ID) information of each layer is set, an access layer specification input and the stored layer identification information are compared and determined, and according to a result of matched or mismatched, each layer is individually accessed. Accordingly, in the layer identification of each layer, many through electrodes and the initial setting are required.

As patent documents relating to the laminated semiconductor devices having stacked semiconductor chips, the following documents have been known. Japanese Unexamined Patent Application Publication No. 2004-95799 discusses a laminated semiconductor device having individual through electrodes in respective layers and each layer is individually accessed. Japanese Unexamined Patent Application Publication No. 2004-264057 discusses a laminated semiconductor device that can individually perform boundary scan for each layer by differently forming connection wiring patterns in each layer from an ID through electrode. Japanese Unexamined Patent Application Publication No. 2006-40261 discusses a laminated semiconductor device that receives an identification command changed in each layer according to an existence of connection between a chip select terminal and an ID through electrode in each layer, and individually accesses a chip in each layer. Japanese Unexamined Patent Application Publication No. 2006-313607 discusses a laminated semiconductor device that performs a logical process of a selection signal from ID through electrodes, selects a chip of each layer, and access the chip.

As described above, all of the known documents discuss to obtain the layer identification information by providing the ID through electrodes in each layer, or differing from the connection wiring patterns of the electrodes. Or, the layer identification information of each layer is set by the logical process. All of the known arts require the dedicated through electrodes or the ID through electrodes, and do not suggest a technique that solves the problem discussed in the present invention.

### SUMMARY OF THE INVENTION

To downsize the large capacity semiconductor devices and to increase the operation speed thereof, development has been made in the above-mentioned manners about the laminated memories that employ the through electrodes. However, the through electrodes of the laminated memory are common to the respective layers, and each layer is connected in parallel with each other. Accordingly, to set the layer identification information of each layer to individually access each layer, it is necessary to provide the dedicated ID through electrodes or the ID through electrodes and the internal circuit. Accordingly, it is an object of the present invention to provide a laminated memory capable of setting layer identification information of each layer using small number of ID through electrodes and individually accessing each layer.

According to an aspect of the present invention, a laminated semiconductor device includes a first semiconductor chip having a first ID through electrode, and a second semiconductor chip having a second ID through electrode that is disposed at a position different from that of the first ID through electrode. The first semiconductor chip and the second semiconductor chip are alternately stacked.

Preferably, the first and second semiconductor chips include internal circuits for generating and storing layer identification information of each layer. The internal circuits of the respective layers are connected in cascade to each other.

Preferably, the first semiconductor chip receives a layer setting input signal from the first ID through electrode and generates layer identification information of the own layer using the internal circuit, and outputs the layer identification information to the second ID through electrode as a layer setting input signal for a next layer.

Preferably, the second semiconductor chip receives a layer setting input signal from the second ID through electrode and generates layer identification information of the own layer using the internal circuit, and outputs the layer identification information to the first ID through electrode as a layer setting input signal for a next layer.

Preferably, the internal circuit has first and second pairs of input and output pads, and the first pair of the input and output pads is disposed near a region where the first ID through electrode is disposed, and the second pair of the input and output pads is disposed near a region where the second ID through electrode is disposed.

Preferably, the internal circuit receives the layer setting input signal from an input pad of the one pair of the input and output pads and generates layer identification information, and outputs the layer identification information from an output pad of the other pair of the input and output pads to connect the internal circuits in each layer in cascade.

Preferably, the first and second ID through electrodes are connected to the input pads and output pads through input and output connection wirings simultaneously formed at the formation of the through electrodes respectively.

Preferably, the internal circuit includes an adder, and the adder receives a layer setting input signal from an input pad of one pair of the input and output pads, generates added layer identification information, and outputs the layer identification information from an output pad of the other pair of the input and output pads to use the adding result as the layer identification information of each layer.

According to another aspect of the present invention, it is provided a layer identification method for a laminated semiconductor device including a first semiconductor chip having a first ID through electrode and a second semiconductor chip having a second ID through electrode that is disposed at a different position from that of the first ID through electrode, the semiconductor chips are alternately stacked. The first semiconductor chip that receives layer identification information from a prior layer generates layer identification information of the own layer in an internal circuit, and outputs the generated layer identification information to the second semiconductor chip of a next layer to generate layer identification information of each layer.

Preferably, the semiconductor chips in the respective layers further include comparison and determination circuits for comparing the generated layer identification information with an input layer identification signal and determining to select or not select each layer.

A laminated memory according to embodiments of the present invention is formed of two types of memory chips that have different positions for disposing ID through electrodes to set layer identification information of the chips of each layer. According to the layers of the laminated memory, the memory chips having the different positions for the ID through electrode are alternately stacked. By alternately stacking the layers, internal circuits of each layer are connected in cascade. With the cascade-connected internal circuits, the internal circuits in each layer can readily generate layer identification information of each layer using setting signals from the ID through electrodes. In the configuration according to the embodiments of the present invention, the layer identification information can be readily set to each memory chip, and the laminated memory capable of individually controlling operation of each layer can be obtained.

### BRIEF DESCRIPTION OF THE DRAWINGS

FIGS. 1A to 1J are cross sectional views illustrating formation of through electrodes and a lamination process according to a first known art;

FIGS. 2A to 2F are cross sectional views illustrating formation of a through electrode and a lamination process according to a second known art;

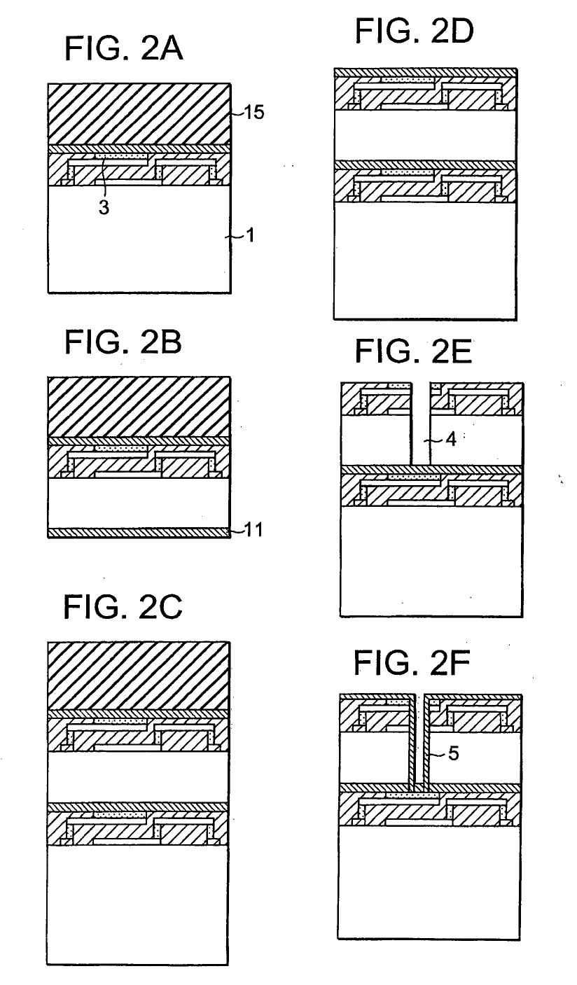

FIGS. 3A and 3B are cross sectional views illustrating the formation of the through electrode and the lamination process according to the second known art;

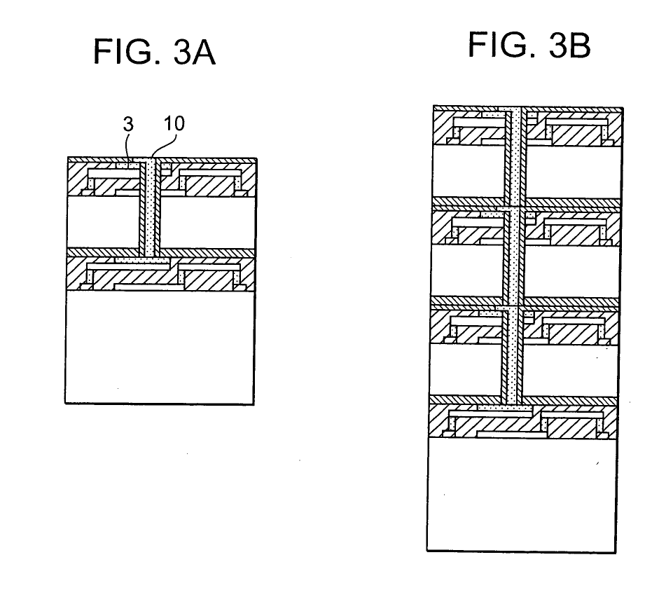

FIG. 4A is a schematic view illustrating a laminated memory according to a first known art, FIG. 4B is a cross sectional view of the laminated memory, and FIG. 4C is a connection diagram of the laminated memory;

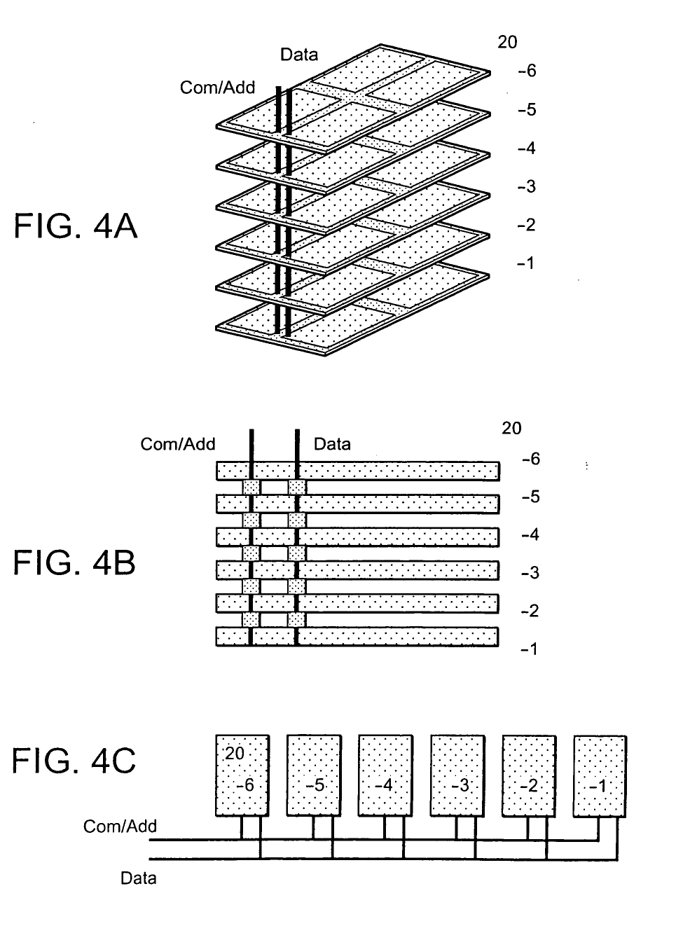

FIGS. 5A to 5C are cross sectional views illustrating an internal circuit for layer identification;

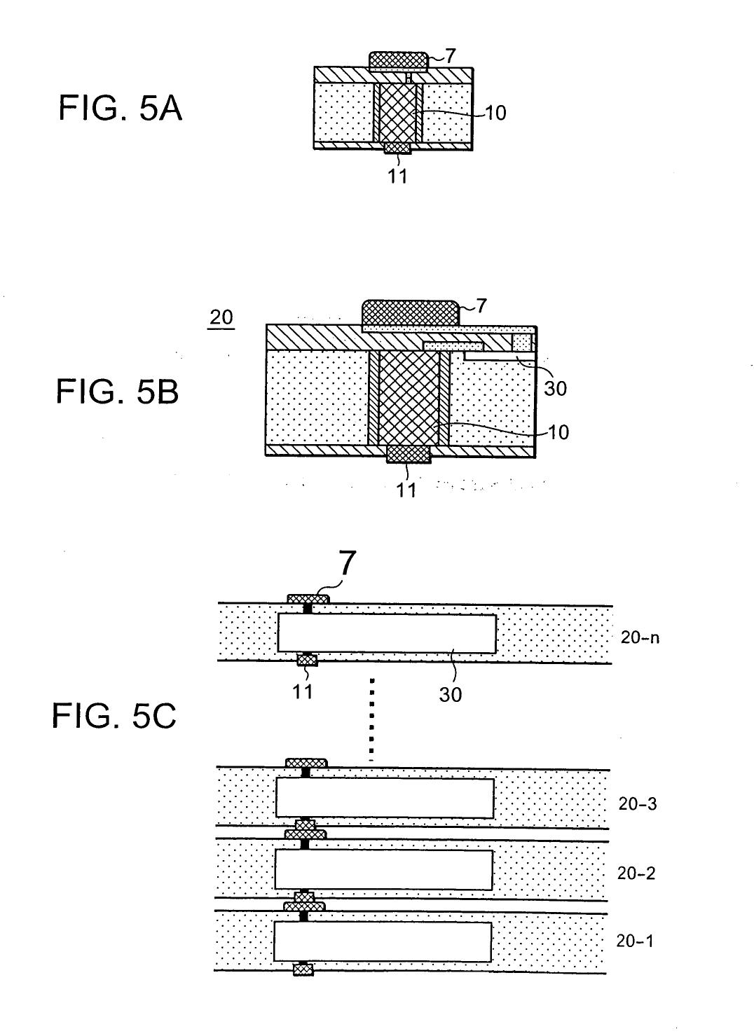

FIG. 6 is a view illustrating a basic configuration of a laminated memory according to an embodiment of the present invention;

FIG. 7 is a view illustrating an internal connection of a laminated memory according to an embodiment of the present invention;

FIG. 8 is a schematic view illustrating a chip of a first layer in a laminated memory according to an embodiment of the present invention;

FIG. 9 is a schematic view illustrating chips of two stacked layers in a laminated memory according to an embodiment of the present invention;

FIG. 10 is a schematic view illustrating chips of three stacked layers in a laminated memory according to an embodiment of the present invention;

FIG. 11 is a schematic view illustrating chips of four stacked layers in a laminated memory according to an embodiment of the present invention; and

FIG. 12 is a schematic view illustrating chips of eight stacked layers in a laminated memory according to an embodiment of the present invention.

### DESCRIPTION OF THE PREFERRED EMBODIMENTS

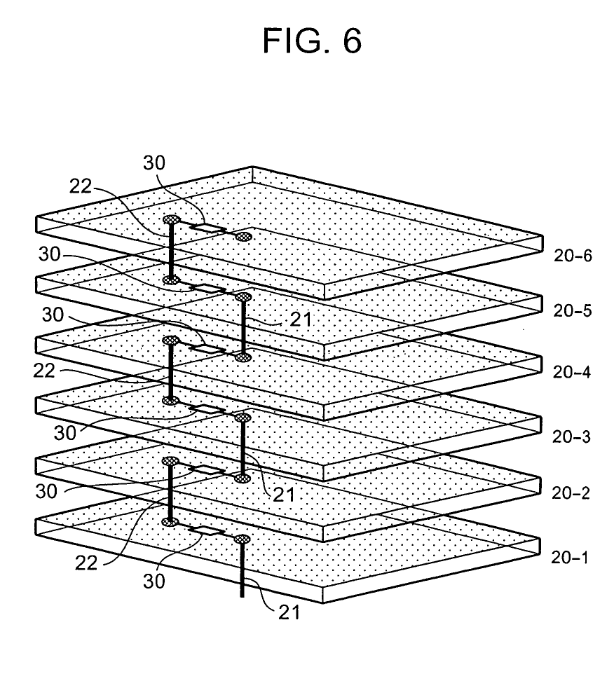

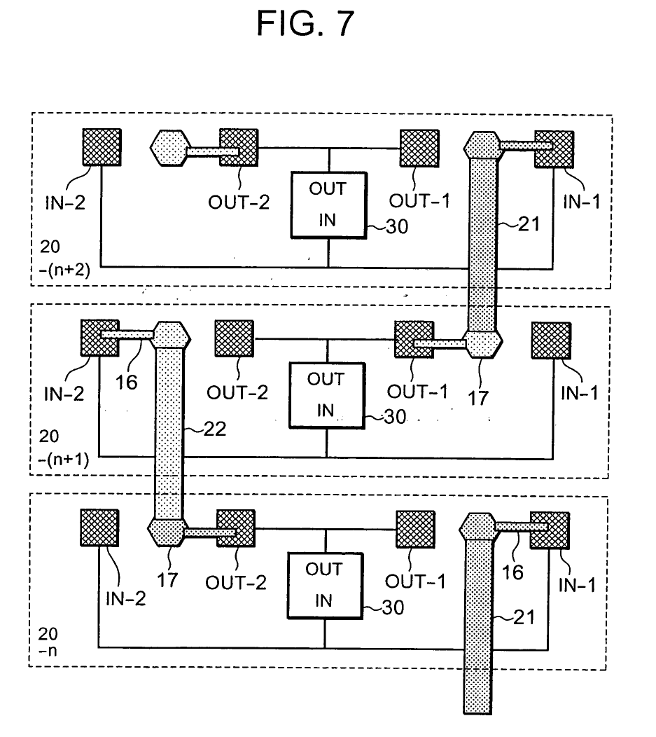

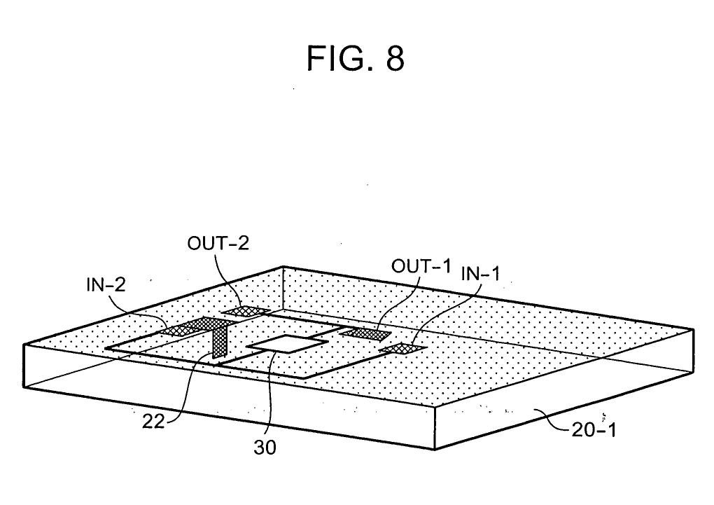

A laminated memory according to an embodiment of the present invention is described in detail with reference to FIGS. 6 to 12. FIG. 6 is a view illustrating a basic configuration of the laminated memory according the embodiment of the present invention. FIG. 7 is a view illustrating an internal connection of the laminated memory. FIGS. 8 to 12 illustrate memory chip lamination processing steps of stacking a first layer to an eighth layer of the laminated memory. In the present embodiment, description is made about a lamination process of a silicon substrate having a very thin thickness of, for example, 30 μm or less. First, silicon substrates that are ground to have a very thin thickness are stacked. Then, a through electrode, pads, and their connection wirings are formed.

In a basic configuration of the laminated memory according to the present embodiment, first memory chips having first ID through electrodes 21 and second memory chips having second ID through electrodes 22 are alternately stacked. As shown in FIG. 6, first, third, and fifth layers are formed by the first memory chips, and second, fourth, and sixth layers are formed by the second memory chips. These layers are alternately stacked respectively. A signal inputted into the ID through electrodes is a layer setting input signal that sets layer identification information of each layer. The first and second memory chips include internal circuits 30 respectively. The internal circuit 30 includes a generation circuit that generates the layer identification information using the layer setting input signal, a storing circuit that stores the identification information, and a comparison and determination circuit that determines match or mismatch of the identification information and determines whether or not each layer is operated.

The internal circuits 30 in the layers of odd numbers that are included in the first memory chips each receive an input signal from ID through electrodes 21 that are shown on the right side in the drawing, and output an output signal to ID through electrodes 22 that are shown on the left side in the drawing. The internal circuits 30 in the layers of even numbers that are included in the second memory chips each receive an input signal from the ID through electrodes 22 on the left side in the drawing, and output an output signal to the ID through electrodes 21 on the right side in the drawing. Accordingly, the disposed positions of the ID through electrodes differ from each other, and the ID through electrodes are alternately disposed on the right side or the left side. The internal circuits 30 receive the input signal from the ID through electrodes of one sides and output the output signal to the ID through electrodes of the other sides respectively. By the configuration, it is possible to connect the internal circuits in the respective layers in cascade to each other.

The configuration of the laminated memory is described in detail with reference to FIG. 7. Memory chips 20 to be stacked include the internal circuits 30 that generate layer identification information using layer setting input signals and store the signals. On the right side of the internal circuit 30, a pair of an input pad IN-1 and an output pad OUT-1 is provided while a pair of an input pad IN-2 and an output pad OUT-2 is provided on the left side of the internal circuit 30.

Generally, as the memory chips 20 in the laminated memory, when an n layer is disposed as a lower layer, layers (n+1) and (n+2) are stacked on the n layer in sequence. Thus, the memory chips are numbered as a memory chip (20-n), a memory chip 20-(n+1), and a memory chip 20-(n+2) respectively.

In the memory chip (20-n), the ID through electrode 21 is formed on the right side of the internal circuit. At the formation of the ID through electrode 21, an input connection wiring 16 that connects the ID through electrode 21 to the input pad IN-1 and an output connection wiring 17 that is connected to the output pad OUT-2 are also formed. The output connection wiring 17 is used to connect to a through electrode of a next memory chip. The input and output connection wirings may be arranged, for example, in a damascene interconnect structure. The internal circuit 30 is connected to the input pad IN-1 and the output pad OUT-2.

The memory chip (20-n) receives a layer setting input signal from the ID through electrode 21 and the input pad IN-1 of the right side and generates layer identification information of the own layer (n layer) in the internal circuit 30. Then, the memory chip (20-n) outputs the generated layer identification information to the output pad OUT-2 and the ID through electrode 22 of an upper layer of the left side. Here, the input pad IN-2 and the output pad OUT-1 are not used. The memory chip (20-n) is the first memory chip that has the ID through electrode 21 formed on the right side of the internal circuit.

In the memory chip (20-(n+1)), the ID through electrode 22 is formed on the left side of the internal circuit. At the formation of the ID through electrode 22, the input connection wiring 16 that connects the ID through electrode 22 to the input pad IN-2 and the output connection wiring 17 that is connected to the output pad OUT-1 are also formed. The ID through electrode 22 is connected to the output connection wiring 17 of the output pad OUT-2 of the memory chip (20-n) of the lower layer and the input connection wiring 16 of the input pad IN-2 of the own layer. The internal circuit is connected to the input pad IN-2 and the output pad OUT-1.

The memory chip (20-(n+1)) receives the layer setting input signal from the ID through electrode 22 and the input pad IN-2 of the left side and generates layer identification information of the (n+1) layer in the internal circuit 30. Then, the memory chip (20-(n+1)) outputs the generated layer identification information to the output pad OUT-1 and the ID through electrode 21 of an upper layer of the right side. Here, the input pad IN-1 and the output pad OUT-2 are not used. The memory chip (20-(n+1)) is the second memory chip that has the ID through electrode 22 formed on the left side of the internal circuit.

In the memory chip (20-(n+2)), the ID through electrode 21 is formed on the right side of the internal circuit. At the formation of the ID through electrode 21, the input connection wiring 16 that connects the ID through electrode 21 to the input pad IN-1 and the output connection wiring 17 that is connected to the output pad OUT-2 are also formed. The ID through electrode 21 is connected to the output connection wiring 17 of the output pad OUT-1 of the memory chip (20-(n+1)) of the lower layer and the input connection wiring 16 of the input pad IN-1 of the own layer. The internal circuit 30 is connected to the input pad IN-1 and the output pad OUT-2.

The memory chip (20-(n+2)) receives the layer setting input signal from the ID through electrode 21 and the input pad IN-1 of the right side and generates layer identification information of the (n+2) layer in the internal circuit 30. Then, the memory chip (20-(n+2)) outputs the generated layer identification information to the output pad OUT-2 and an upper layer of the left side. Here, the input pad IN-2 and the output pad OUT-1 are not used. The memory chip (20-(n+2)) is the first memory chip that has the ID through electrode 21 formed on the right side of the internal circuit.

As described above, the first memory chips have the ID through electrodes 21 formed on the right side of the internal circuits, and the next second memory chips have the ID through electrodes 22 formed on the left side of the internal circuits. By alternately stacking the layers, the internal circuits in each layer can be connected in cascade (dependent). With the cascade connection of the internal circuits, the layer identification information generated in each layer is used as the layer setting input signal for the next layer. Accordingly, the layer identification information in each layer can be readily set.

As the internal circuits 30 in FIG. 7, for example, an adder (+1) or a subtacter may be used. For example, if the adder (+1) is used as the internal circuit 30, the adders in the memory chips 20 sequentially add from the lower layer 1, 2, 3, 4, and +1, and output the results. Accordingly, the result of the adding in the order of the stacked layers is used as the output of each internal circuit, and is used as the layer identification information (identification number, ID) of each layer. Based on a matching result between the layer identification information and an address (bank+Row) inputted from another through electrode group (not shown) or the like, it is possible to select to operate or not to operate each layer.

Now, the lamination process steps of each layer are described with reference to FIGS. 8 to 12. FIG. 8 illustrates a memory chip 20-1 that is the first layer. The memory chip is formed by grinding a silicon substrate to be very thin, and includes a supporting body (not shown) on a rear surface. On a front surface of the memory chip, the internal circuit 30 is formed, on the right side of the internal circuit 30, a pair of the input pad IN-1 and the output pad OUT-1 is formed, and on the left side, a pair of the input pad IN-2 and the output pad OUT-2 is formed. On the left side of the internal circuit 30, the through electrode 22 is formed. Further, an input connection wiring that is connected to the input pad IN-2 and an output connection wiring that is connected to the output pad OUT-1 are formed. The memory chip 20-1 is called the second memory chip specified by the ID through electrode 22 formed on the left side of the internal circuit.

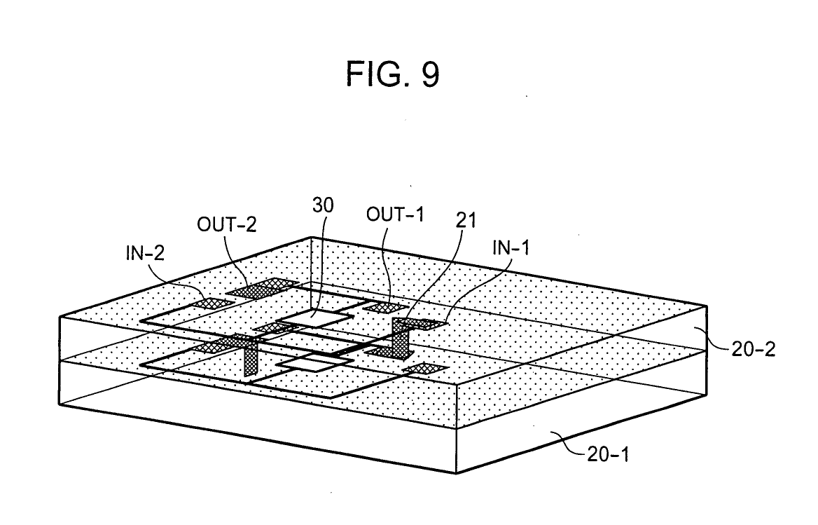

On the memory chip 20-1, a memory chip 20-2, which forms the second layer, is stacked (FIG. 9). The silicon substrate of the memory chip 20-2 is ground to be very thin. The memory chip 20-2 includes the internal circuit 30 on the front surface, the pair of the input pad IN-1 and the output pad OUT-1 on the right side of the internal circuit 30, and the pair of the input pad IN-2 and the output pad OUT-2 on the left side of the internal circuit 30. On the memory chip 20-2, the through electrode 21 is formed on the right side of the internal circuit 30, and further, the input connection wiring that is connected to the input pad IN-1 and the output connection wiring that is connected to the output pad OUT-2 are formed. The memory chip 20-2 is called the first memory chip specified by the ID through electrode 21 formed on the right side of the internal circuit.

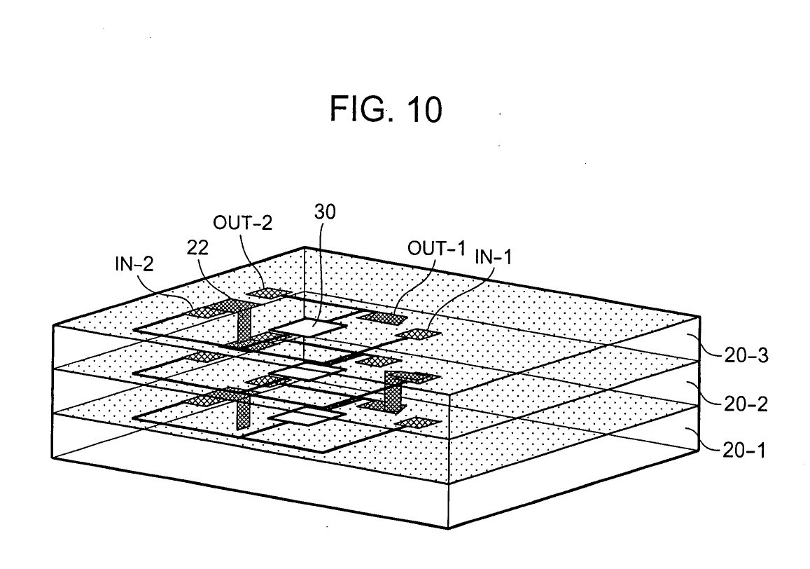

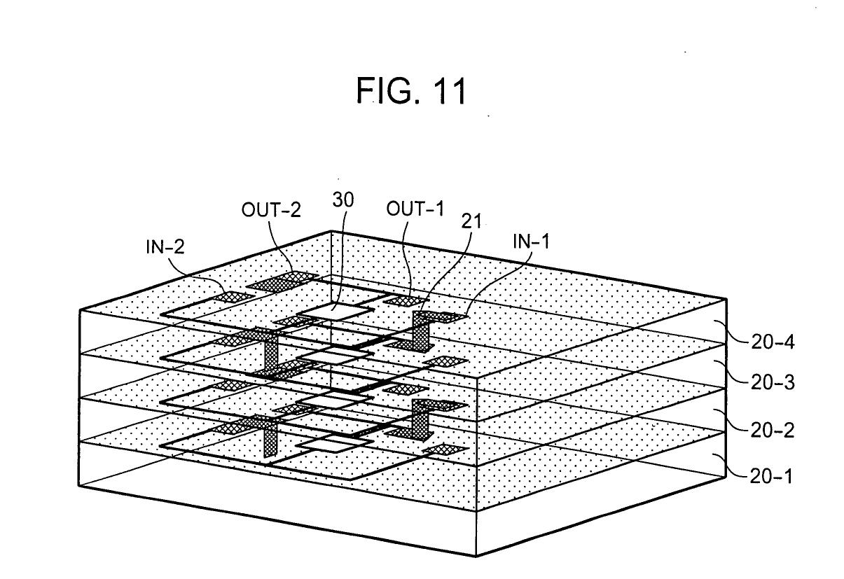

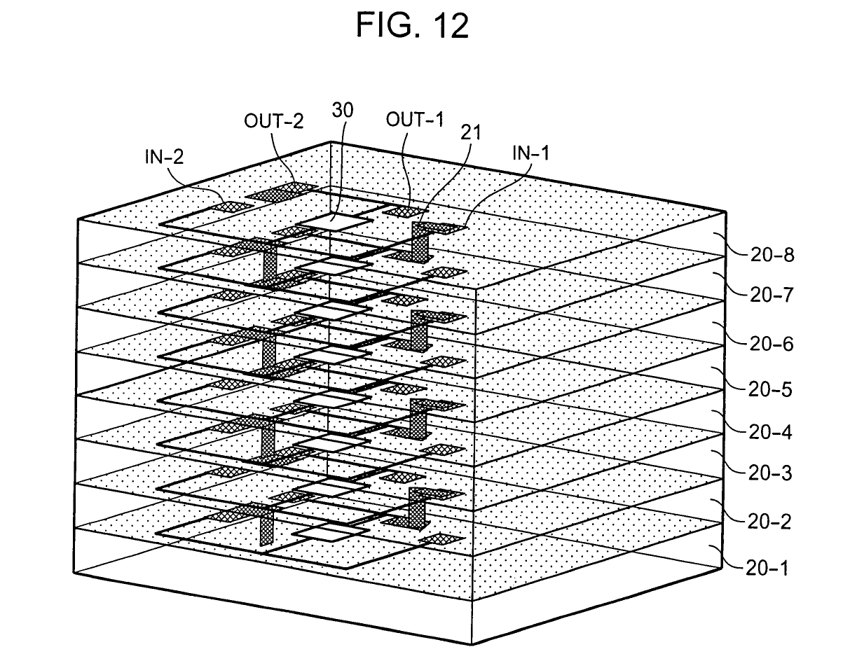

Similarly, as shown in FIG. 10, a memory chip 20-3, which is the third layer, is further stacked. On the memory chip 20-3, the through electrode 22, the input connection wiring that is connected to the input pad IN-2 and the output connection wiring that is connected to the output pad OUT-1 are formed. Further, as shown in FIG. 11, a memory chip 20-4, which is the fourth layer, is further stacked. On the memory chip 20-4, the through electrode 21, the input connection wiring that is connected to the input pad IN-1 and the output connection wiring that is connected to the output pad OUT-2 are formed. FIG. 12 shows a laminated memory that has stacked eight layers. As described above, by alternately stacking the second memory chips and the first memory chips, the laminated memory is formed. The internal circuits for layer identification information of the respective layers are connected in cascade. With the cascade connection, it is possible to readily identify each layer, and it is possible to select to operate or not to operate each layer.

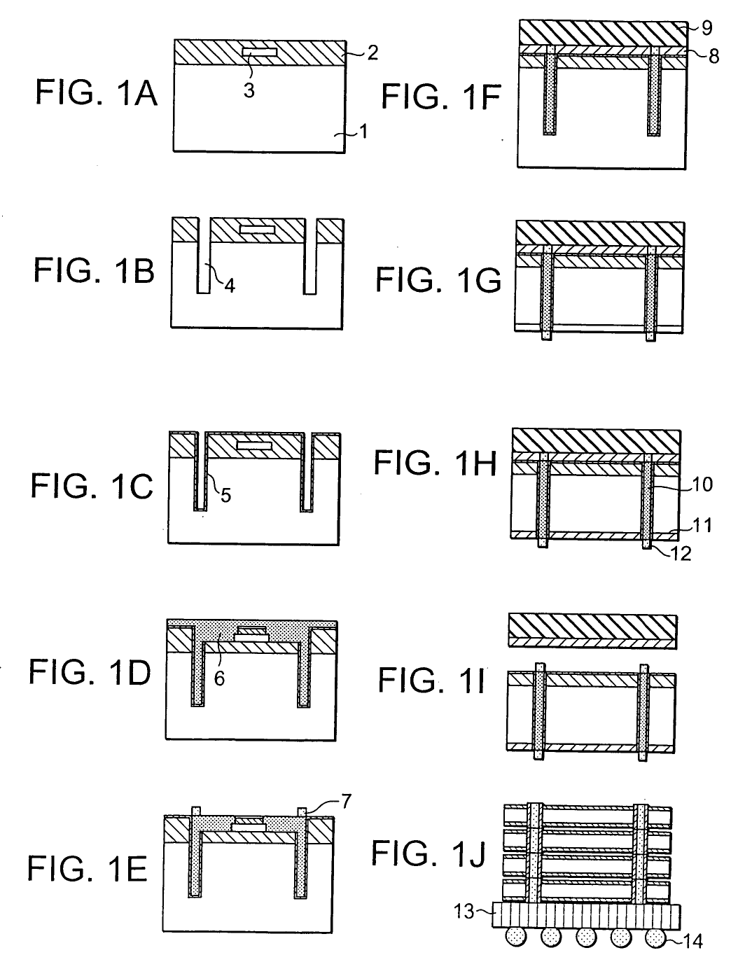

In the above description, the chips that are formed by grinding the silicon substrates to be very thin are stacked, and the through electrodes and the input and output connection wirings are formed. However, similar to the case of FIG. 1, the laminated memory may be formed by forming the through electrode and the input and output connection wirings of the chip, grinding the chip, and stack the chips. In this case, two types of chips, that is, the first chip having the ID through electrode on the right side of the internal circuit and the second chip having the ID through electrode on the left side of the internal circuit are formed. The laminated memory according to the embodiment of the present invention may be formed by alternately stacking the first chip and the second chip. Further, in the present embodiment, the ID through electrode is formed on the left side or the right side of the internal circuit. However, the configuration is not limited to the above example. If it is possible to provide connection wirings at one side of the through electrode and the input/output pads respectively and the connection wirings are connected with each other, the through electrode may be disposed on any region.

The laminated memory according to the embodiment of the present invention is formed by alternately stacking the first and second memory chips that have different positions to dispose the ID through electrodes that set the layer identification information of each layer. Because the positions to dispose the ID through electrodes differ from each other, the internal circuits for layer identification information of each layer are connected in cascade. For example, if the internal circuits are formed by adders, the layer identification information of each layer can be readily generated. By identifying the layer identification information, it is possible to select to operate or not to operate each layer. According to the embodiment of the present invention, by alternately stacking the first and second memory chips that have different positions to dispose the ID through electrodes, it is possible to obtain the laminated memory that can readily identify each layer.

While the present invention has been described with reference to the embodiments, it is to be understood that the invention is not limited to the above-described embodiments. Various modifications can be made without departing from the scope of the invention, and it is to be understood that the modifications are within the scope of the invention. For example, the embodiments of the present invention have been described using the laminated memory formed by stacking the memory chips. However, it is not limited to the memory, but the invention can be applied to other semiconductor chips. In addition, the present invention may include at least the first and the second ID through electrodes connected in cascade to each other and may also prepare three or more ID different through electrodes stacked in semiconductor chips and connected in cascade.

What is claimed is:

1. A laminated semiconductor device comprising:
a first semiconductor chip having a first ID through electrode; and
a second semiconductor chip having a second ID through electrode that is disposed at a position different from that of the first ID through electrode,
wherein the first semiconductor chip and the second semiconductor chip are alternately stacked.

2. The laminated semiconductor device according to claim 1, wherein the first and second semiconductor chips include internal circuits for generating and storing layer identification information related to respective layers.

3. The laminated semiconductor device according to claim 2, wherein the first semiconductor chip receives a layer setting input signal from the first ID through electrode and generates layer identification information of the own layer using the internal circuit, and outputs the layer identification information to the second ID through electrode as a layer setting input signal for a next layer.

4. The laminated semiconductor device according to claim 2, wherein the second semiconductor chip receives a layer setting input signal from the second ID through electrode and generates layer identification information of the own layer using the internal circuit, and outputs the layer identification information to the first ID through electrode as a layer setting input signal for a next layer.

5. The laminated semiconductor device according to claim 4, wherein the internal circuit has first and second pairs of input and output pads, and the first pair of the input and output pads is disposed near a region where the first ID through electrode is disposed, and the second pair of the input and output pads is disposed near a region where the second ID through electrode is disposed.

6. The laminated semiconductor device according to claim 5, wherein the internal circuit receives the layer setting input signal from an input pad of the one pair of the input and output pads and generates layer identification information, and outputs the layer identification information from an output pad of the other pair of the input and output pads to connect the internal circuits in each layer in cascade.

7. The laminated semiconductor device according to claim 6, wherein the first and second ID through electrodes are connected to the input pads and output pads through input and output connection wirings simultaneously formed at the formation of the through electrodes respectively.

8. The laminated semiconductor device according to claim 5, wherein the internal circuit includes an adder, and the adder receives a layer setting input signal from an input pad of one pair of the input and output pads, generates added layer identification information, and outputs the layer identification information from an output pad of the other pair of the input and output pads to use the adding result as the layer identification information of each layer.

9. A layer identification method for a laminated semiconductor device including a first semiconductor chip having a first ID through electrode and a second semiconductor chip having a second ID through electrode that is disposed at a position different from that of the first ID through electrode, the semiconductor chips being alternately stacked,
wherein the first semiconductor chip that receives layer identification information from a prior layer generates layer identification information of the own layer in an internal circuit, and outputs the generated layer identification information to the second semiconductor chip of a next layer to generate layer identification information of each layer.

10. The layer identification method for the laminated semiconductor device according to claim 9, wherein the semiconductor chips in each layer further include comparison and determination circuits for comparing the generated layer identification information with an input layer identification signal and determining whether or not each layer is selected.

11. The laminated semiconductor device according to claim 1, wherein the first and second semiconductor chips include internal circuits for generating and storing layer identification information related to respective layers and wherein the internal circuits are connected in cascade to each other.
